(19) United States
(12) Patent Application Publication
(10) Pub. No.: US 2006/0024964 A1
(43) Pub. Date: Feb. 2, 2006

(54) Method and apparatus of forming thin film using atomic layer deposition

(76) Inventors: Jung-Hun Seo, Gyeonggi-do (KR); Young-Wook Park, Gyeonggi-do (KR); Jin-Gi Hong, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/154,045

(22) Filed: Jun. 15, 2005

(30) Foreign Application Priority Data
Jul. 27, 2004 (KR) 2004-58591

(51) Int. Cl. H01L 21/44; C23C 16/00

(52) U.S. Cl. 438/680; 118/724; 438/685

(57) ABSTRACT

The method of forming a TiN thin film using an atomic layer deposition (ALD) method includes thermally decomposing TiCl₄; introducing a pyrolyzed product of the TiCl₄ into the chamber; supplying a first purge gas into the chamber; supplying a reactant gas into the chamber, thereby forming a TiN thin film; and supplying a second purge gas into the chamber. The apparatus of forming a TiN thin film includes a gas conduit having an entrance line into which a source gas, TiCl₄ is introduced; a heater installed around the gas conduit and thermally decomposing the introduced source gas, TiCl₄, in advance to make a secondary source gas; and a chamber being connected to the gas conduit and having a reaction room in which the TiN thin film is formed by the reaction of the secondary source gas and NH₃ as a reactant gas. Therefore, a TiN thin film growth rate can be improved.

### CROSS-REFERENCE TO RELATED APPLICATION

This application claims the benefit of Korean Patent Application No. 10-2004-0058591, filed Jul. 27, 2004, the disclosure of which is hereby incorporated herein by reference in its entirety.

### BACKGROUND OF THE INVENTION

1. Technical Field

The present invention relates to a method of forming a thin film and, more particularly, to a method of forming a TiN thin film by an atomic layer deposition providing an improved thin film growth rate and an apparatus thereof.

2. Discussion of Related Art

Generally, a thin film is widely used for dielectrics of a semiconductor device, a transparent conductor of a liquid crystal display, a protective layer of an electroluminescent thin film display, and the like.

It is desired that thin films used for dielectrics of a semiconductor device should be formed without any impurities or defects inside the dielectrics and the interface thereof in order to ensure a high capacitance and suppress a leakage current. Further, the thin film must provide excellent step coverage and an excellent uniformity.

Typical methods for forming a thin film of a semiconductor device include both chemical and physical methods. In the chemical method, a source gas undergoes a chemical reaction to form a solid material. In the physical method, material particles are deposited on a substrate through various physical schemes.

Chemical vapor deposition (CVD), one of the chemical methods, includes steps of introducing various reaction gases into a reaction chamber to react with each other, and growing a solid material produced from the resulting reaction on a substrate. More specifically, when a gas is supplied on the substrate inside the reaction chamber through a gas supplier, the gas is thermally pyrolyzed by the heat supplied from a heater, thereby forming a thin film without changing of the property of the substrate. The CVD method is widely used to form thin films because of its use in employing various kinds of composite materials, its adaptability to the composition of high impurity materials, and its allowance to perform precisely controlled processes. However, the typical CVD method used to form a thin film does not generally provide excellent step coverage. If the CVD method employs a deposition process using a surface kinetic mode, the dielectrics can be expected to have relatively excellent step coverage. However, it is difficult to selectively control the step coverage in a specific portion of the dielectrics since reactant materials to be deposited for the dielectrics reach the substrate concurrently. Further, a deposition process forming a thin film by the CVD method is performed at a relatively high temperature. As a result, the CVD method may cause thermal effects unfavorable to semiconductor devices. Further, the CVD method cannot provide a thin film with enough uniform thickness to satisfy the demand of highly integrated circuit structures.

Recently, in order to solve the above problems, methods of forming the thin film have been proposed that provide excellent step coverage by periodically supplying reactant materials on the surface of a substrate on which the thin film will be formed, so as to activate a surface kinetic region. The methods include an atomic layer deposition (ALD) method, a cyclic CVD method, a digital CVD method, an advanced CVD method, and the like.

The ALD method forms a thin film by decomposing reactant materials through periodical supply of each reactant material and chemical exchange of the materials; not by pyrolysis. That is, necessary source gases are not mixed inside a reaction chamber, but each source gas is individually introduced into the reaction chamber by pulse type in the ALD method. Specifically, when a first source gas and a second source gas are used to form a thin film, only the first source gas is first introduced into the reaction chamber, thereby to be chemically adsorbed on a substrate. Then, the second source gas is introduced into the reaction chamber, thereby to be chemically adsorbed on the substrate. Thus, a thin film is formed as an atomic layer. The ALD method provides excellent step coverage characteristics and improved uniformity and step coverage in comparison with the CVD method. The ALD method also operates under a low temperature process. Further, since the ALD method forms a thin film by atomic layering, the thin film formed has excellent characteristics. Typical examples of the ALD method include deposition of Al₂O₃ used as dielectrics of a cylindrical capacitor of a 1 Gig DRAM device, and deposition of a material, such as TiN and Ru, used as an upper electrode and a lower electrode. Furthermore, since the CVD method is not appropriate for providing stable step coverage for such a capacitor of a device having a very high aspect ratio, the ALD method is essentially required.

A TiCl₄-based CVD TiN thin film used as a barrier layer or a top electrode of a capacitor, which is formed by a CVD process using TiCl₄ as a source gas, is known to provide excellent step coverage. However, even the TiCl₄ based CVD TiN thin film cannot be expected to ensure satisfactory step coverage when the aspect ratio is increased up to about 20 or more, due to flux differences supplied to the inside of a hole and the surface thereof. Therefore, it is preferable to form a thin film by the ALD method, in which the thin film is formed only by complete surface reaction, in order to overcome the disadvantage.

A TiN thin film formed by the ALD method will be referred to as an ALD TiN, and the formation process is as follows. Main reactant gases forming the ALD TiN are TiCl₄ and NH₃. In order to deposit the ALD TiN, TiCl₄ gas is flowed over a substrate so as to be adsorbed on the substrate. After the adsorption, inert gas is supplied to purge the not-adsorbed, remaining, overflow TiCl₄ out of the reaction chamber. Then, NH₃ is flowed to react with the adsorbed TiCl₄, thereby forming a TiN atomic layer thin film. The temperature necessary for reaction in the formation process is in the range of 200 to 500° C. When the TiN thin film is formed by the ALD method, since the process is performed at a low temperature, formation of the TiN thin film causes no unfavorable thermal effects to semiconductor devices. That is, the TiN thin film formed by the ALD method allows the deposition at a lower temperature than that of the typical CVD process, thereby providing more excellent step coverage and denser layer properties.

Even with the above advantages, the conventional TiN thin film formation method has problems as follows. In the conventional technology, one monolayer is theoretically impossible to form per one cycle due to the molecular volume of source gas. For example, in the case of forming a TiN thin film using TiCl₄ gas as a source gas, and using existing atomic layer deposition equipment when one cycle is 1.5 seconds, a thin film growth rate is in the range of 0.2 to 0.4 Å/cycle. This thin film growth rate is significantly low compared to the thin film growth rate by the existing CVD method, about 7˜10 Å/sec. Consequently, the conventional ALD TiN thin film formation having this low thin film growth rate is difficult to effectively employ within existing semiconductor device fabrication processes.

Therefore, it is required to propose a thin film deposition method having a high growth rate with the advantages of the ALD process.

### SUMMARY OF THE INVENTION

Therefore, the present invention is directed to provide a method of fabricating a semiconductor device and an apparatus thereof to solve the problems of the conventional technology.

Another object of the present invention is to provide a method of forming a TiN thin film for increasing a deposition rate by improving the reaction of an ALD process, and an apparatus of forming a TiN thin film.

Still another object of the present invention is to provide a method of forming a TiN thin film for improving a TiN thin film growth rate by decomposing component elements of a source gas, for example, TiCl₄ into TiClₓ and Cl group(s) and thus, decreasing an effect of steric hinderance, and an apparatus of forming a thin film.

Exemplary embodiments of the present invention provide a method of forming a TiN thin film using an ALD method, including thermally decomposing TiCl₄; introducing a pyrolyzed product of the TiCl₄ into the chamber; supplying a first purge gas into the chamber; supplying a reactant gas into the chamber, thereby forming a TiN thin film; and supplying a second purge gas into the chamber.

Preferably, a heater for thermally decomposing TiCl₄ is installed outside the reaction chamber, and operates such that the outside of a gas conduit, into which the source gas, TiCl₄, is introduced, is heated up to a predetermined temperature or higher, to make a temperature of the source gas at about 350° C. or higher.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a flow chart illustrating a method of forming a TiN thin film according to a first embodiment of the present invention;

FIG. 2 is a view illustrating an apparatus for forming a TiN thin film of FIG. 1;

FIG. 3 is a flow chart illustrating a method of forming a TiN thin film according to a second embodiment of the present invention; and

FIG. 4 is a view illustrating an apparatus for forming a TiN thin film of FIG. 3.

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided as teaching examples of the invention. Like numbers refer to like elements.

First, a technical principle of the present invention uses an effect of steric hinderance due to molecular volume and structure. The low thin film growth rate problem of the TiN thin film formation method using the conventional ALD method is known to be caused from steric hinderance due to molecular volume and structure of source material itself. The source gas used in the TiN thin film formation method is TiCl₄. In TiClₓ gas, TiCl₃ has been found to be less affected by steric hinderance than TiCl₄, and TiCl₂ less affected by steric hinderance than TiCl₃. Therefore, the thin film growth rate can be improved when using the ALD method, by decomposing TiCl₄ into TiCl₃ and TiCl₂, and flowing the TiCl₃ and TiCl₂ onto a substrate. Therefore, according to the present invention, there are provided a method of forming a TiN thin film for improving a TiN thin film growth rate using this discovery, and an apparatus thereof.

### EMBODIMENT 1

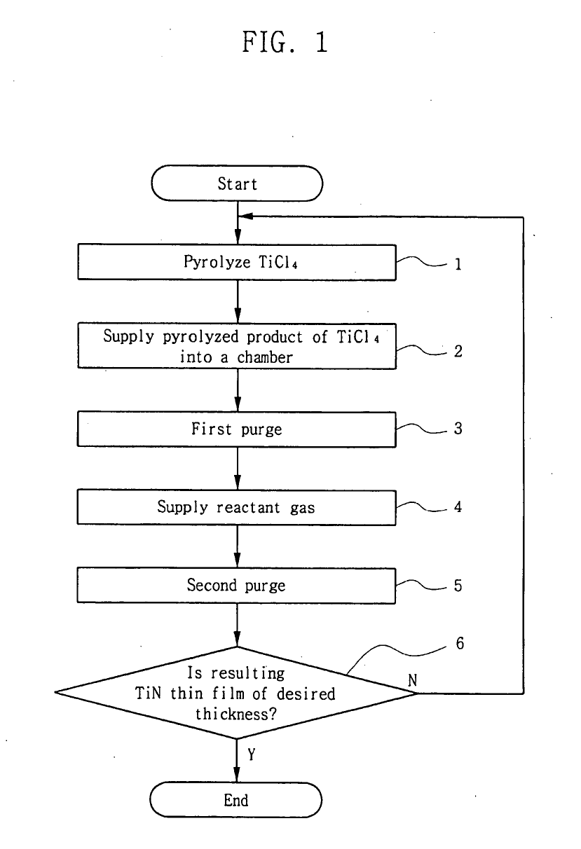

FIG. 1 is a flow chart illustrating a method for forming a TiN thin film according to a first embodiment of the present invention.

In the method for forming a TiN thin film according to a first embodiment of the present invention, titanium chloride (TiCl₄) is thermally pyrolyzed into TiCl₃ or TiCl₂, and an atomic layer deposition (ALD) process is performed using the TiCl₃ or TiCl₂ as a source gas.

As shown in FIG. 1, the formation of the TiN thin film may be performed as follows.

In a first step 1, titanium chloride (TiCl₄) as a source gas is heated using a heater, and is made to be thermally pyrolyzed into TiCl₃ or TiCl₂. In a preferred embodiment, the titanium chloride (TiCl₄) must be heated at a temperature of about 350° C. or higher to thermally pyrolyze the titanium chloride (TiCl₄).

In a second step 2, the pyrolyzed product, TiCl₃ or TiCl₂ is introduced into a chamber having a substrate on which a TiN thin film will be formed.

In a third step 3, a first purge gas is supplied into the chamber to remove the source gas and a pyrolyzed by-product. The first purge gas uses an inert gas such as Ar.

In a fourth step 4, a reactant gas is supplied into the chamber so as to form a TiN thin film. The preferred reactant gas uses ammonia (NH₃).

In a fifth step 5, a second purge gas is supplied into the chamber to remove the remaining reactant gas and by-product. The second purge gas may use a gas different from the first purge gas.

When defining the above steps as one cycle—that is, a step of thermally decomposing, a step of supplying a source gas, a step of supplying a first purge gas, a step of supplying a reactant gas, and a step of supplying a second purge gas—the one cycle may be repeatedly performed (step 6) dozens or thousands of times until a TiN thin film with a desired thickness is formed.

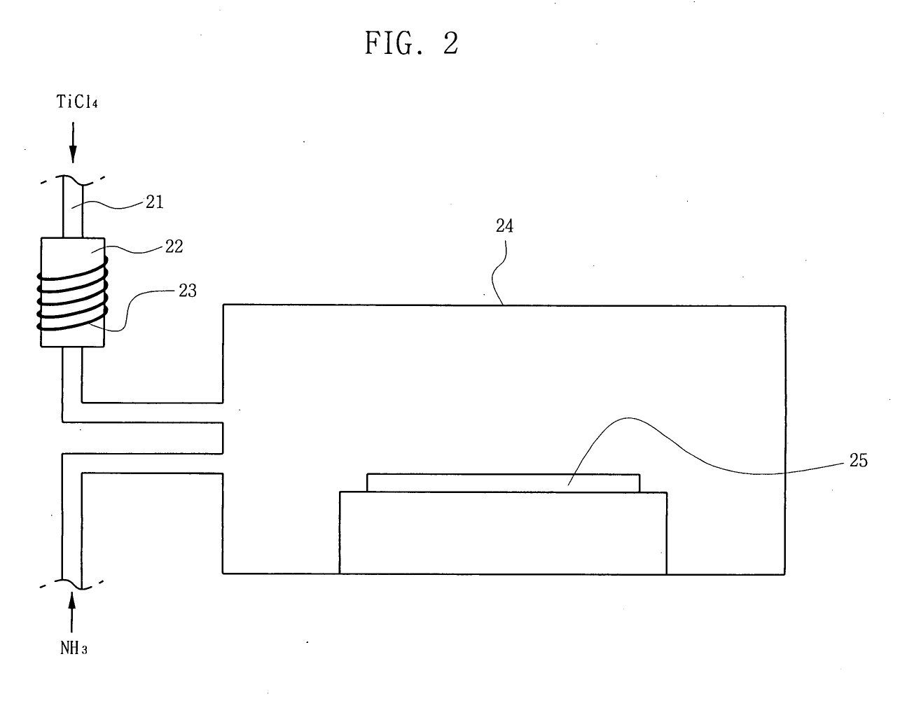

FIG. 2 is a view illustrating an apparatus for forming a TiN thin film using the process of FIG. 1.

Referring to FIG. 2, the titanium chloride (TiCl₄) being used as a source gas to form a TiN thin film is introduced through an entrance line 21 into a gas conduit 22. Around the gas conduit 22, there is installed a heater 23 to thermally pyrolyze the source gas, that is, titanium chloride (TiCl₄). The source gas, that is, titanium chloride (TiCl₄) is heated by the heater 23 up to a temperature of 350° C. or higher, so as to be thermally pyrolyzed into TiCl₃ or TiCl₂. The heater 23 is installed outside or insulated from of a reaction chamber 24. As such, when the heater 23 heats the source gas, the inner temperature of the reaction chamber 24 is not increased. Then, the thermal decomposition product—that is, TiCl₃ or TiCl₂—is introduced as a secondary source gas through the gas conduit 22 into the reaction chamber 24. The secondary source gas, that is, TiCl₃ or TiCl₂, is flowed over the substrate 25 so as to be adsorbed on the substrate 25. When the adsorption is completed, the inside of the reaction chamber is purged using an inert gas such as Ar. Then, NH₃ is introduced into the reaction chamber 24 so as to react with the TiCl₃ or TiCl₂, which is adsorbed on the substrate, thereby forming a TiN thin film monolayer. Then, the inside of the reaction chamber is again purged. The processes are repeatedly performed until a TiN thin film with a desired thickness is formed. As a result, using the TiCl₃ or TiCl₂ (which has little vulnerability to steric hindrance) as a source gas to perform the ALD method causes the thin film growth rate to be improved up to 5 Å/cycle.

### EMBODIMENT 2

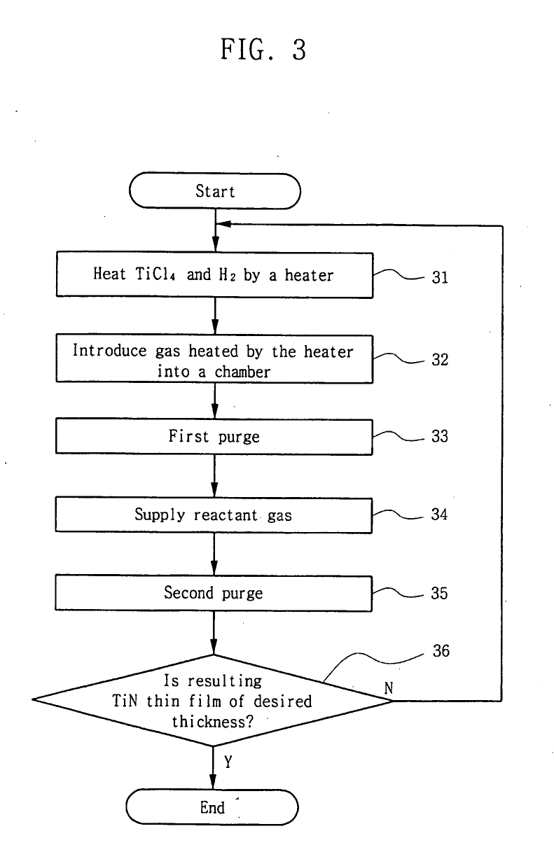

FIG. 3 is a flow chart illustrating a method of forming a TiN thin film according to a second embodiment of the present invention.

In the method of forming a TiN thin film according to a second embodiment of the present invention, titanium chloride (TiCl₄) is pyrolyzed using heat and hydrogen (H₂) gas into TiCl₃ or TiCl₂, and an atomic layer deposition (ALD) process is performed using the TiCl₃ or TiCl₂ as a source gas.

As shown in FIG. 3, the formation of the TiN thin film may be performed as follows.

In a first step 31, titanium chloride (TiCl₄) as a source gas and hydrogen (H₂) gas as a decomposition accelerant gas are heated using a heater. The reason to heat the H₂ and the TiCl₄ together is to activate the H₂ so as to maximize the decomposition effect of the TiCl₄. The titanium chloride (TiCl₄) must be heated at a temperature of 350° C. or higher to pyrolyze the titanium chloride (TiCl₄).

In a second step 32, the heated gas by the heater in the first step is introduced into a chamber having a substrate on which a TiN thin film will be formed.

In a third step 33, a first purge gas is supplied into the chamber to remove the source gas and a by-product. The first purge gas uses an inert gas.

In a fourth step 34, a reactant gas is supplied into the chamber so as to form a TiN thin film. The reactant gas preferably uses ammonia (NH₃).

In a fifth step 35, a second purge gas is supplied into the chamber to remove the remained reactant gas and a by-product. The second purge gas may use a gas different from the first purge gas.

When defining the above steps as one cycle—that is, a step of decomposing, a step of supplying a source gas, a step of supplying a first purge gas, a step of supplying a reactant gas, and a step of supplying a second purge gas—the one cycle may be repeatedly performed (step 36) dozens or thousands of times until a TiN thin film with a desired thickness is formed.

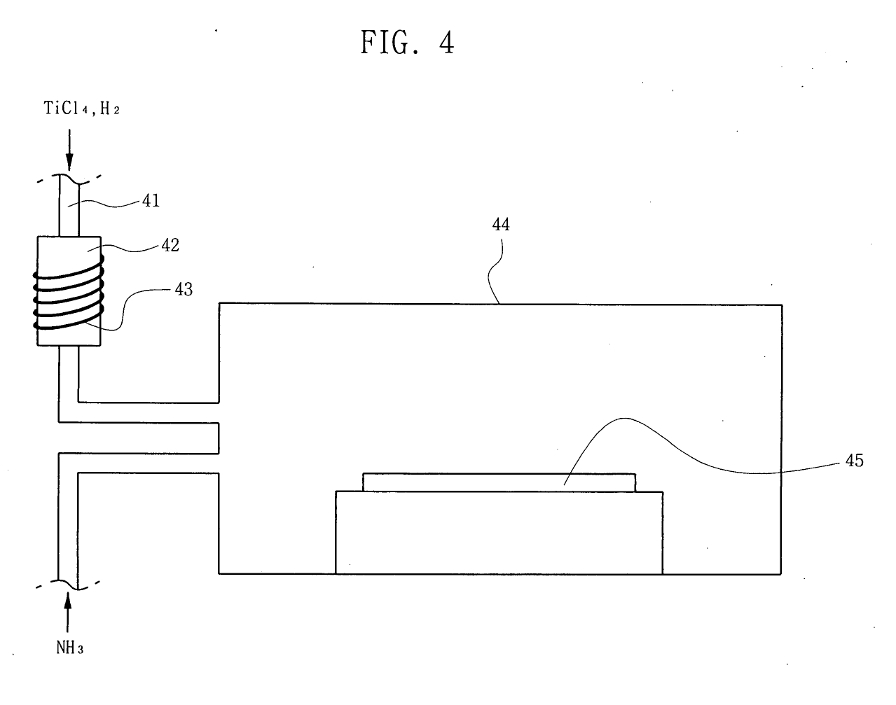

FIG. 4 is a view illustrating an apparatus for forming a TiN thin film of FIG. 3.

Referring to FIG. 4, TiCl₄ and H₂ are allowed to pass through heater 42.

TiCl₄ (used as a source gas to form a TiN thin film) and H₂ (used as an accelerant gas to activate the decomposition of the TiCl₄) are introduced through an entrance line 41 into a gas conduit 42. A heater 43 is installed round the gas conduit 42. The TiCl₄ and H₂ are heated by the heater 43 up to a temperature of 350° C. or higher. The reason for heating the H₂ using the heater 42 is to activate the H₂ by heating, so as to maximize the decomposition effect of the TiCl₄. As such, the source gas, that is, TiCl₄ is pyrolyzed into TiCl₃ or TiCl₂. The heater 43 is installed outside or insulated from a reaction chamber 44. As such, when the heater 43 heats the source gas, the inner temperature of the reaction chamber 44 does not increase. Subsequently, the thermal decomposition product, that is the secondary source gas TiCl₃ or TiCl₂, is introduced through the gas conduit 42 into the reaction chamber 44. This secondary source gas is flowed over the substrate 45 so as to be adsorbed on the substrate 45. When the adsorption is completed, the inside of the reaction chamber is purged using an inert gas such as Ar. Then, NH₃ is introduced into the reaction chamber 44 so as to react with the TiCl₃ or TiCl₂ which is adsorbed on the substrate, thereby forming a monolayer TiN thin film. Then, the inside of the reaction chamber is again purged. The processes are repeatedly performed until a TiN thin film with a desired thickness is formed. As TiCl₃ or TiCl₂ is less vulnerable to steric hindrance as a source gas in the ALD process, the thin film growth rate can be improved up to 5 Å/cycle.

### EMBODIMENT 3

In another embodiment of the present invention, TiCl₄ is first introduced into a chamber holding the substrate on which the thin film is to be formed. H2 is then heated by a heater and introduced into the chamber to activate and thereby decompose the TiCl₄. The pre-heating of the H₂ is to maximize the decomposition of TiCl₄. As such, the pyrolyzed product of such a process—TiCl₃ or TiCl₂—is adsorbed on the substrate. Then, NH₃ is introduced as a reactant gas into the chamber, so as to react with the TiCl₃ or TiCl₂ adsorbed on the substrate, thereby forming a TiN thin film.

As described above, according to the embodiments of the present invention, the method of forming the TiN thin film and the apparatus thereof can provide an improved growth rate of the TiN thin film while using a low temperature process in an ALD process.

Furthermore, the method of forming the TiN thin film and the apparatus thereof according to the present invention improve the throughput per unit time by solving a conventional problem of a low growth rate of a thin film in the typical ALD method. In addition to the high growth rate of a thin film, the inherent advantages of the ALD method—that is, excellent step coverage, excellent surface coverage, and dense layer property—are maintained. The reliability of semiconductor devices fabricated is therefore improved, and production costs are decreased. Furthermore, price competitiveness of the products is also improved.

The method of forming the TiN thin film and the apparatus thereof of the present invention have been described using preferred exemplary embodiments. However, it is to be understood that the scope of the invention is not limited to the disclosed embodiments. On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

What is claimed is:

1. A method for forming a thin film having a component element of a source gas during an atomic layer deposition (ALD) process, the method comprising the step of thermally pyrolyzing a source gas to form a secondary source gas prior to a step of introducing the source gas into a chamber in which the thin film is formed.

2. The method of claim 1, further including the step of introducing a reactant gas into the chamber after the secondary source gas is introduced into the chamber.

3. The method of claim 2, wherein the reactant gas is NH₃.

4. The method of claim 1, further including:
providing a substrate within the chamber onto which the thin film is grown; and
flowing the secondary source gas over the substrate so that at least a portion of the secondary source gas is absorbed on the substrate.

5. The method of claim 4, further including the steps of:
supplying a first purge gas into the chamber so as to evacuate a non-absorbed portion of the secondary source gas;
introducing a reactant gas into the chamber so as to react with the portion of secondary source gas absorbed on the substrate thereby forming a thin film.

6. The method of claim 5, wherein the first purge gas is an inert gas.

7. The method of claim 5, further including the step of supplying a second purge gas into the chamber after the reactant gas is introduced into the chamber.

8. The method of claim 7, wherein the second purge gas is different from the first purge gas.

9. The method of claim 1, wherein the source gas is TiCl₄, the secondary source gas is TiCl₂ or TiCl₃, and the thin film is TiN.

10. The method of claim 9, wherein the TiCl₄ source gas is thermally pyrolyzed using a heater.

11. The method of claim 10, wherein the heater heats the TiCl₄ source gas at a temperature of above about 350° C.

12. The method of claim 10, further including the step of configuring the heater around a gas conduit into which the TiCl₄ source gas is introduced.

13. The method of claim 1, further including the step of heating a decomposition accelerant together with the source gas prior to introducing the secondary source gas into the chamber.

14. The method of claim 13, wherein the decomposition accelerant is H₂.

15. The method of claim 14, wherein the step of heating is performed at a temperature of above about 350° C.

16. A method for forming a thin film having a component element of a source gas during an atomic layer deposition (ALD) process, the method comprising the step of thermally pyrolyzing a source gas within a chamber in which the thin firm is to be formed by introducing a heated gas into the chamber with the source gas to create a secondary source gas.

17. The method of claim 16, further including:
providing a substrate within the chamber onto which the thin film is grown; and
flowing the secondary source gas over the substrate so that at least a portion of the secondary source gas is absorbed on the substrate.

18. The method of claim 17, further including the steps of:
supplying a first purge gas into the chamber so as to evacuate a non-absorbed portion of the secondary source gas;
introducing a reactant gas into the chamber so as to react with the portion of secondary source gas absorbed on the substrate thereby forming a thin film.

19. The method of claim 18, wherein the reactant gas is NH₃.

21. The method of claim 18, wherein the first purge gas is an inert gas.

22. The method of claim 18, further including the step of supplying a second purge gas into the chamber after the reactant gas is introduced into the chamber.

23. The method of claim 22, wherein the second purge gas is different from the first purge gas.

24. The method of claim 16, wherein the source gas is TiCl₄, the secondary source gas is TiCl₂ or TiCl₃, and the thin film is TiN.

25. The method of claim 24, wherein the heated gas is H₂.

26. The method of claim 25, wherein the heated gas is heated using a heater and wherein the heater heats heated gas at a temperature of above about 350° C.

27. The method of claim 25, further including the step of configuring the heater around a gas conduit into which the H₂ heated gas is introduced.

28. An apparatus of forming a thin film using an atomic layer deposition (ALD), the apparatus comprising:
a gas conduit having an entrance line into which a source gas is introduced;
a heater installed around the gas conduit and being adapted to thermally decompose the introduced source gas to make a secondary source gas; and
a chamber being connected to the gas conduit and having a reaction room in which a desired thin film containing a component element of the source gas is formed by the reaction with a predetermined reactant gas.

29. The apparatus according to claim 28, wherein the heater heats a gas passing through the gas conduit at a temperature of 350° C. or higher to thermally pyrolyze the source gas upstream of the chamber.

30. The apparatus according to claim 28, wherein the source gas is TiCl₄.

31. The apparatus according to claim 28, wherein the secondary source gas is TiCl₂ or TiCl₃.

32. The apparatus according to claim 28, wherein the desired thin film is TiN.

33. The apparatus according to claim 28, wherein the reactant gas is NH₃.

34. The apparatus according to claim 28, further including means using an inert gase for purging the chamber during formation of the desired thin firm.
